(19) United States
(12) Patent Application Publication
(10) Pub. No.: US 2026/0190270 A1
(43) Pub. Date: Jul. 2, 2026

(54) IMMERSION SERVER CABINET

(71) Applicant: ABLECOM TECHNOLOGY INC., Taoyuan City (TW)

(72) Inventor: Chien-Fa LIANG, Taoyuan City (TW)

(21) Appl. No.: 19/073,052

(22) Filed: Mar. 7, 2025

(30) Foreign Application Priority Data
Dec. 27, 2024 (TW) 113214339

(51) Int. Cl. H05K 7/14; H05K 7/20

(52) U.S. Cl. CPC H05K 7/1489; H05K 7/20236; H05K 7/20781

(57) ABSTRACT

An immersion server cabinet having a cabinet body, two carrying brackets, and a server module is provided. Each of the carrying brackets is arranged in the cabinet body and includes a frame body and a fixing cover arranged on the frame body to form a plugging space. Each of the fixing covers has two clamping elastic arms. The server module is detachably connected to the carrying brackets and includes a server body and two connecting assemblies. Each of the connecting assemblies is arranged on two opposite sides of the server body and includes an abutting plate and a positioning track. The abutting plates are placed on the frame bodies. The positioning tracks are inserted into the plugging spaces and clamped and fixed by the clamping elastic arms. The server module is therefore mounting stably between the carrying brackets and absorbing vibration or shaking through the clamping elastic arms.

### BACKGROUND

### Technical Field

The present disclosure relates to the field of liquid cooling, particularly to an immersion server cabinet.

### Description of Related Art

With the rapid development of artificial intelligence (AI), the demand for server usage and server performance have greatly improved such that servers generate a large amount of heat energy during operation. Therefore, in order to maintain servers within a certain temperature range to ensure their working efficiency and lifespan, most servers are placed in a cabinet and immersed in coolant to cool and dissipate heat to improve heat dissipation efficiency.

However, in the transporting and assembling of the most existing immersion server cabinets, the server is first installed in the server cabinet, then the server cabinet is transported to the customer, and then the customer fills the cabinet with coolant for use. Nevertheless, the immersion server cabinet typically experiences bump or vibration during transport, which causes servers inside to bounce, shake or collide to lead to damage.

In view of the above, the inventor seeks to overcome the aforementioned drawbacks associated with the current technology and aims to provide an effective solution through extensive researches along with utilization of academic principles and knowledge.

### SUMMARY

The primary objective of the present disclosure is to make the server module to be mounted stably between the carrying brackets, so as to absorb vibration or shaking through the clamping elastic arms of the carrying brackets during transportation.

To accomplish the aforementioned objective, the present disclosure provides an immersion server cabinet having a cabinet body, a pair of carrying brackets, and a server module. The cabinet body has a chamber and a pair of mounting walls. Each of the mounting walls is located on two opposite sides of the chamber. Each of the carrying brackets is arranged on each of the mounting walls and includes a frame body and a fixing cover. Each of the frame body has a groove. Each of the fixing covers has a pair of clamping elastic arms. The fixing cover of each of the carrying brackets is mounted on the frame body and forms a plugging space with the groove. The server module is detachably connected to the carrying brackets and accommodated in the chamber. The server module includes a server body and a pair of connecting assemblies. Each of the connecting assemblies is arranged on two opposite sides of the server body and includes an abutting plate and a positioning track. Each of the abutting plates is placed on each of the frame bodies. Each of the positioning tracks is inserted into each of the plugging spaces and clamped and fixed by each of the clamping elastic arms.

In the immersion server cabinet of the present disclosure, each of the fixing covers and each of the grooves together form the plugging space such that each of the positioning tracks of the server module may be respectively inserted into each of the plugging spaces and clamped and fixed by each of the clamping elastic arms of the fixing cover. Each of the abutting plates is placed on each of the frame bodies to support and fix such that the server module may be mounted stably between the carrying brackets. The immersion server cabinet of the present disclosure may absorb vibration or shaking of the server module through the carrying brackets during transportation.

### BRIEF DESCRIPTION OF THE DRAWINGS

FIG. 1 is a perspective appearance view of the present disclosure;

FIG. 2 is an exploded view of the present disclosure;

FIG. 3 is a partial perspective appearance view of the server module of the present disclosure;

FIG. 4 is a partial perspective appearance view of the carrying bracket of the present disclosure;

FIG. 5 is a partial cross-sectional side view of the server module before mounting of the present disclosure;

FIG. 6 is a partially enlarged view of FIG. 5;

FIG. 7 is a partial cross-sectional front view of the server module before mounting of the present disclosure;

FIG. 8 is a partial cross-sectional side view of the server module after mounting of the present disclosure;

FIG. 9 is a partially enlarged view of FIG. 8; and

FIG. 10 is a partial cross-sectional front view of the server module after mounting of the present disclosure.

### DETAILED DESCRIPTION

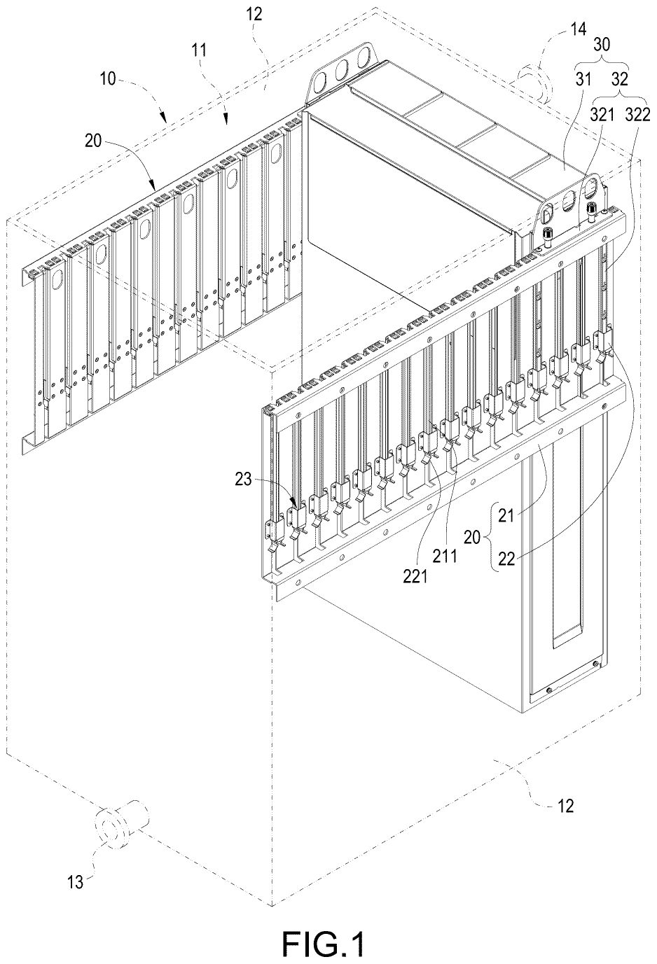

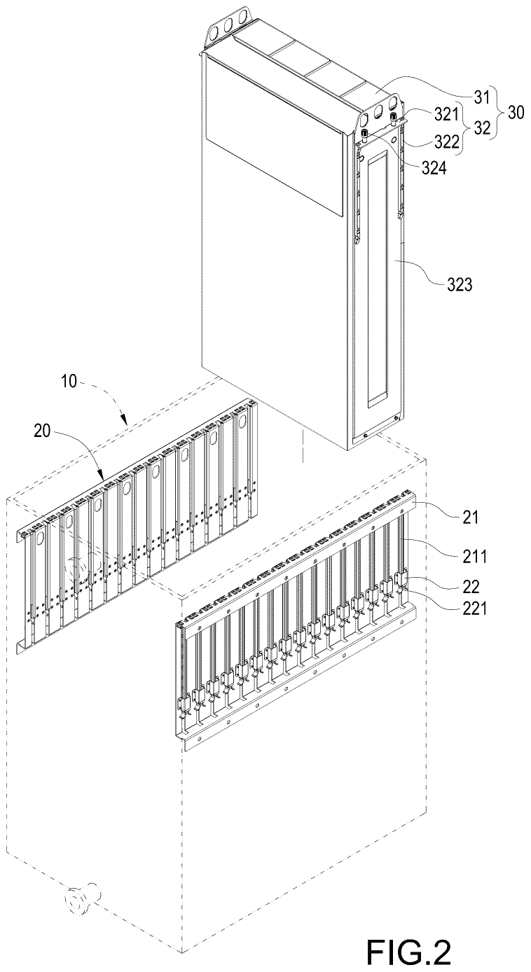

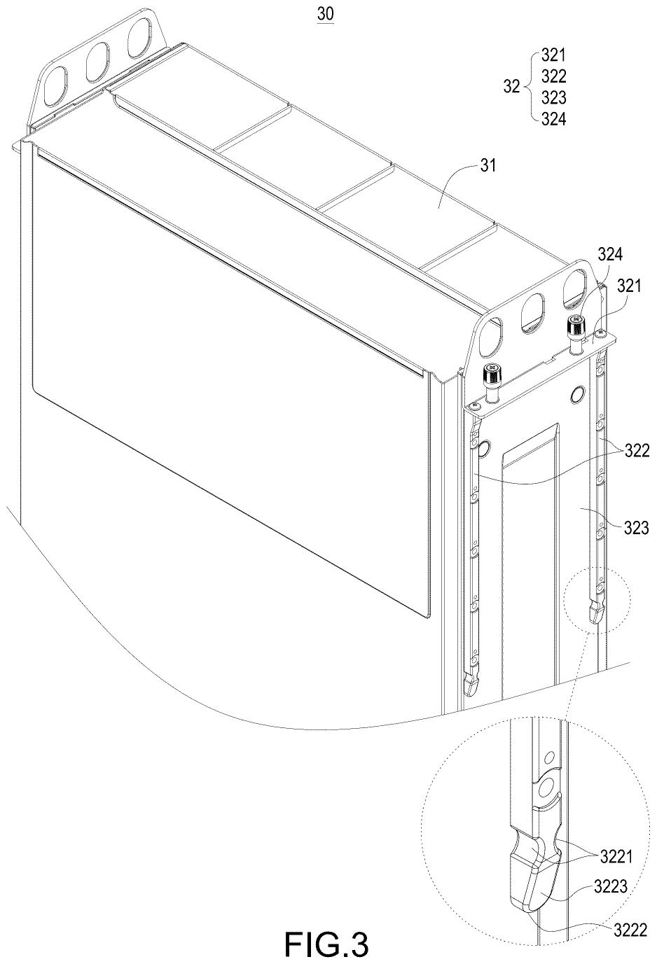

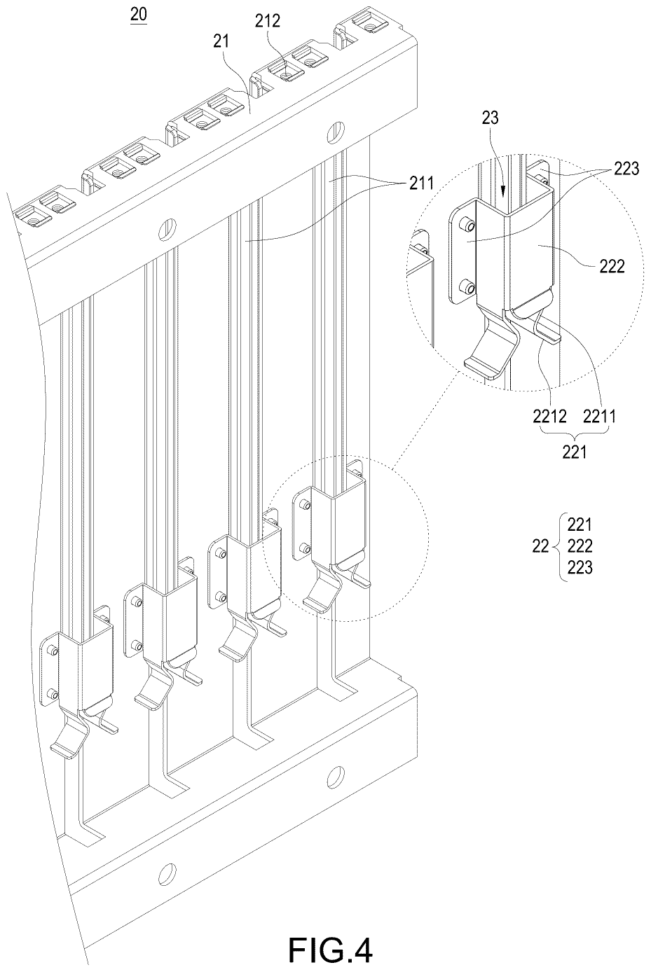

The present disclosure provides an immersion server cabinet, which is used to fill a coolant (not shown in figures) to perform liquid cooling to a plurality of server modules 30 therein. Please refer to FIG. 1, FIG. 2, FIG. 3, and FIG. 4, the immersion server cabinet of the present disclosure mainly includes a cabinet body 10, a pair of carrying brackets 20, and at least one server module 30. It should be noted that the immersion server cabinet of the present disclosure may include a plurality of server modules 30 according to different needs. In order to simplify illustration, only one server module 30 is shown in figures. For the convenience of description, only one server module 30 is used in the following description. However, the present disclosure is not limited to only one server module 30.

In the embodiment, the cabinet body 10 is a hollow rectangular body, but the present disclosure is not limited to this embodiment. A shape of the cabinet body 10 may be modified according to different needs, as long as the cabinet body 10 is hollow. The cabinet body 10 has a chamber 11, a pair of mounting walls 12, an inlet port 13, and an outlet port 14. Each of the mounting walls 12 is located on two opposite sides of the chamber 11. In the embodiment, the mounting walls 12 are respectively located on left side and right side of the chamber 11, but the present disclosure is not limited to this embodiment. The inlet port 13 and the outlet port 14 are respectively communicated to the chamber 11 to input or output the coolant into or from the chamber 11. In detail, the inlet port 13 of the embodiment is arranged on a front side of the cabinet body 10 and adjacent to a bottom of the chamber 11, and the outlet port 14 of the embodiment is arranged on a rear side of the cabinet body 10 and adjacent to a top of the chamber 11, but the present disclosure is not limited to this embodiment. Therefore, a low-temperature coolant may perform heat exchange after entering from the bottom of the chamber 11, and then the low-temperature coolant heats up and leaves from the top of the chamber 11.

Each of the carrying brackets 20 is arranged on each of the mounting walls 12. Each of the carrying brackets 20 includes a frame body 21 and at least one fixing cover 22. Each of the frame bodies 21 defines at least one groove 211. In each of the carrying brackets 20, a number of the fixing cover 22 and a number of the groove 211 are both plural for mounting the server modules 30. In the embodiment, the frame body 21 of each of the carrying brackets 20 is extended along a longitudinal direction (that is a front-rear direction of the cabinet body 10) and is substantially rectangular, and each of the grooves 211 of each of the frame bodies 21 is substantially arranged in parallel along the longitudinal direction. In addition, in each of the frame body 21, each of the grooves 211 is extended downward from a top of the frame body 21. In the embodiment, each of the grooves 211 passes through a left-right direction of each of the frame bodies 21, but the present disclosure is not limited to this embodiment. In each of the carrying brackets 20, each of the fixing covers 22 is mounted on a side of the corresponding frame body 21 away from the other carrying bracket 20, and each of the fixing covers 22 is configured to be corresponding to each of the grooves 211. In other words, each of the fixing covers 22 of each of the carrying brackets 20 is substantially arranged on the corresponding frame body 21 in parallel along the longitudinal direction. Each of the fixing covers 22 forms a plugging space 23 with the corresponding grooves 221. Each of the fixing covers 22 has a pair of clamping elastic arms 221. In the embodiment, each of the clamping elastic arms 221 of each of the fixing covers 22 is extended toward the bottom of the chamber 11.

The server module 30 is detachably connected to each of the carrying brackets 20 and accommodated in the chamber 11 such that the server module 30 may totally immerse in the coolant in the chamber 11 to perform liquid cooling. The server module 30 includes a server body 31 and a pair of connecting assemblies 32. The connecting assemblies 32 are respectively arranged on two opposite sides of the server body 31, that is each of the connecting assemblies 32 is arranged correspondingly to each of the carrying brackets 20. Each of the connecting assemblies 32 mainly includes an abutting plate 321 and at least one positioning track 322. When the server module 30 is assemble to each of the carrying brackets 20, each of the abutting plates 321 is placed on each of the frame bodies 21 to support, and each of the positioning tracks 322 is inserted into each of the plugging spaces 23 and clamped and fixed by each of the clamping elastic arms 221. In the embodiment, each of the connecting assemblies 32 includes a pair of positioning tracks 322, and each of the positioning tracks 322 is substantially arranged perpendicularly to the abutting plate 321, but the present disclosure is not limited to this embodiment. For example, a number of the positioning track 322 in each of the connecting assemblies 32 may also be one, three or more. Therefore, each of the positioning tracks 322 may improve stability when inserting into each of the plugging spaces 23, and each of the positioning tracks 322 may also reduce size, volume, weight, and cost thereof while ensuring stability.

The frame bodies 21 located on two sides of the cabinet body 10 support the abutting plates 321 of two sides of the server module 30, and each of the positioning tracks 322 is inserted into each of the plugging spaces 23 and clamped and fixed by each of the clamping elastic arms 221. Therefore, the server module 30 may be limited and positioned in the front-rear direction and the left-right direction while ensuring sufficient support, such that the immersion server cabinet of the present disclosure may absorb vibration or shaking of the server module 30 through each of the clamping elastic arms 221 of each of the carrying brackets 20 during transportation.

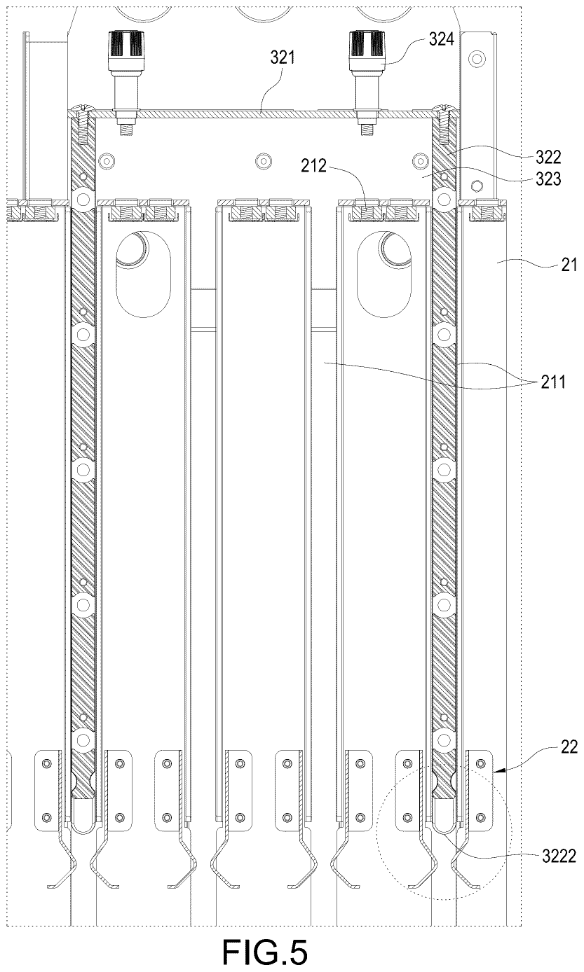

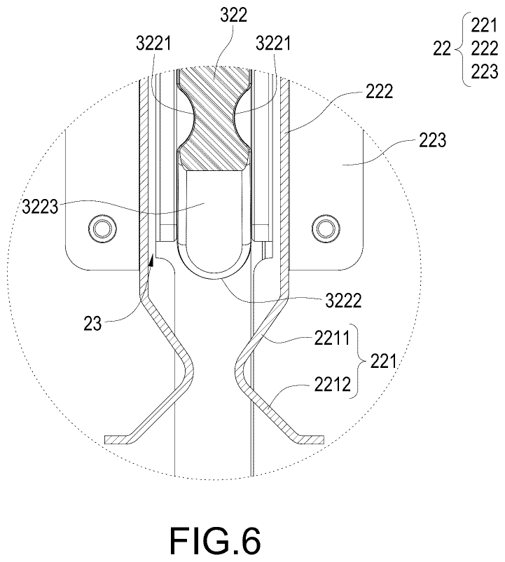

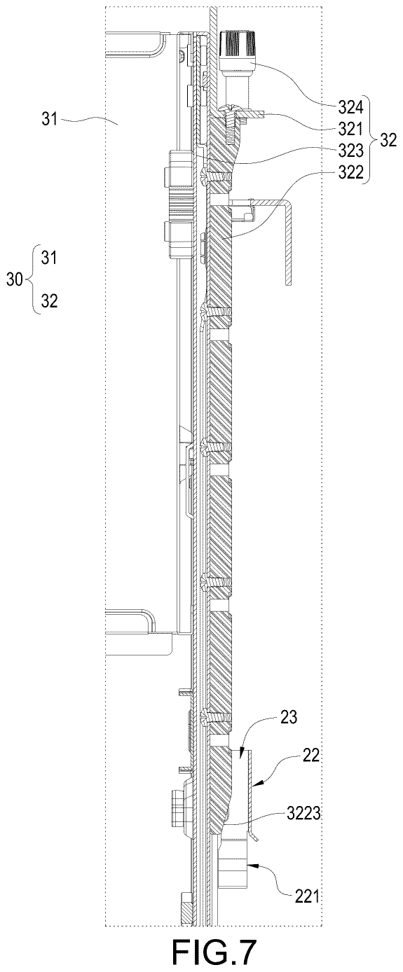

Please refer to FIG. 4, FIG. 5, FIG. 6, and FIG. 7, each of the fixing covers 22 includes a cover shell 222 and a pair of mounting portions 223. The cover shell 222 of each of the fixing covers 22 and the corresponding groove 211 together form the plugging space 23. In the embodiment, each of the cover shells 222 is U-shaped, but the present disclosure is not limited to this embodiment. For example, each of the cover shells 222 may also be arc-shaped or other shapes, as long as each of the cover shells 222 may form the corresponding plugging space 23 with the corresponding groove 211. In each of the fixing covers 22, each of the mounting portions 223 is plate-shaped and connected to two opposite sides of the cover shell 222. Each of the mounting portions 223 of each of the fixing cover 22 is arranged on the corresponding frame body 21 and located on two sides of the corresponding groove 211, such that each of the fixing covers 22 may be stably mounted on the corresponding frame body 21 to prevent each of the positioning tracks 322 from being tilted while being inserted into each of the plugging spaces 23.

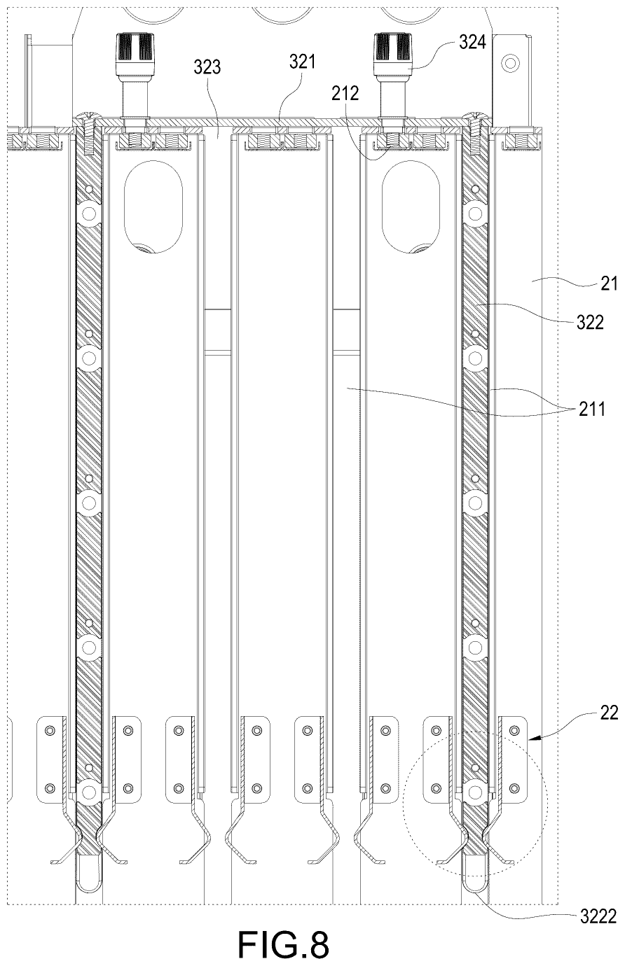

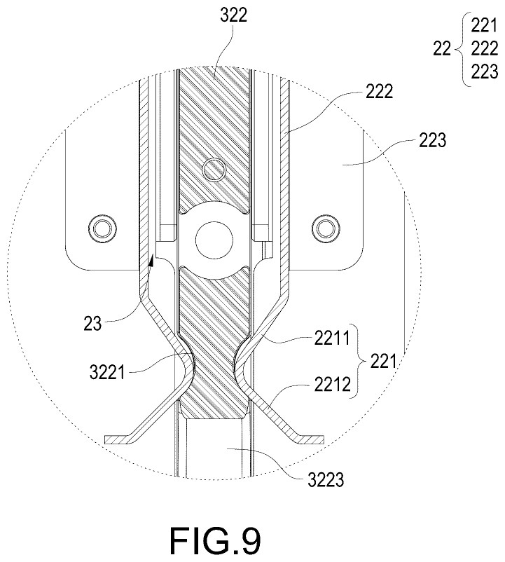

Details are provided as follows. The clamping elastic arms 221 in each of the fixing cover 22 are oppositely extended from the corresponding shell cover 222. In detail, each of the clamping elastic arms 221 in each of the fixing cover 22 is extended from the corresponding shell cover 222 toward the bottom of the chamber 11. Each of the clamping elastic arms 221 includes a shrinking section 2211 and an expanding section 2212. In each of the fixing cover 22, each of the shrinking sections 2211 is extended obliquely from the cover shell 222 toward the other shrinking section 2211, and each of the expanding sections 2212 is extended from an end of the corresponding shrinking section 2211 away from the other expanding section 2212. Therefore, each of the clamping elastic arms 221 in each of the fixing covers 22 is arranged opposite one another, that is each of the clamping elastic arms 221 in each of the fixing covers 22 is bending toward the other clamping elastic arm 221 to make a turning point of each of the clamping elastic arms 221 (the turning point between the shrinking section 2211 and the expanding section 2212) to be configured to be adjacent to a central area of each of the clamping elastic arms 221, so as to form a clamping structure with the turning point inward and an opening outward. In other words, each of the clamping elastic arms 221 forms a clamping portion (not labeled in figures) facing to the other clamping elastic arm 221 at the turning point between the shrinking section 2211 and the expanding section 2212, such that each of the clamping elastic arms 221 in each of the fixing covers 22 may clamp the corresponding positioning track 322 through opposite clamping portions, as shown in FIG. 8 and FIG. 9. In addition, each of the positioning tracks 322 has a pair of notches 3221 arranged opposite to each other. Each of the notches 3221 in each of the positioning tracks 332 is located on an end of the positioning track 332 corresponding to the fixing cover 22. Therefore, each of the clamping portions of each of the clamping elastic arms 221 of each of the fixing covers 22 elastically clamps to each of the notches 3221 of two sides of the corresponding positioning track 322, so as to fix the corresponding positioning track 322 without shaking or vibrating.

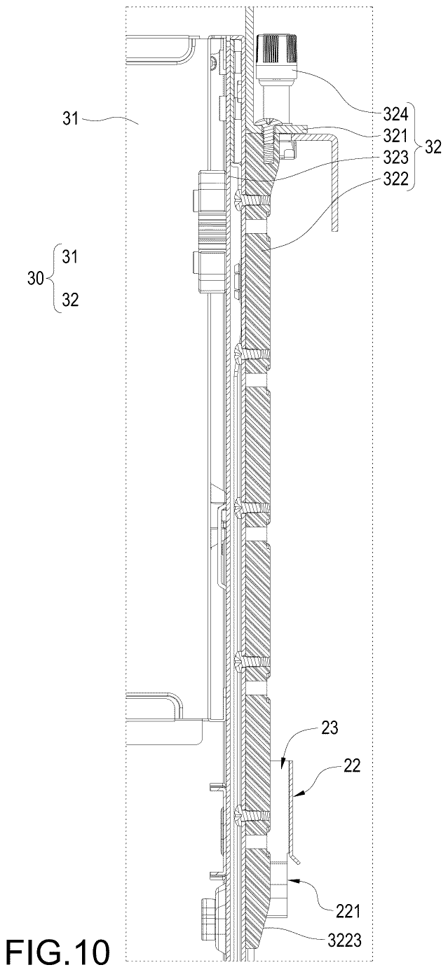

In addition, please refer to FIG. 5, FIG. 6, FIG. 7, FIG. 8, FIG. 9, and FIG. 10. Each of the positioning tracks 322 has an arc end surface 3222 and a guiding slope 3223. Each of the arc end surfaces 3222 is located on an end of the corresponding positioning track 322 corresponding to the fixing cover 22 and facing to the fixing cover 22, that is the arc end surface 3222 in each of the positioning tracks 322 is facing to the bottom of the chamber 11. Therefore, the arc end surface 3222 may perform a guiding effect without impacting the corresponding clamping elastic arms 221 to cause damage when each of the positioning tracks 322 is inserted into each of the plugging spaces 23. In addition, the arc end surface 3222 may push outward each of the clamping elastic arms 221 during the insertion of the positioning track 322 until the positioning track 322 is inserted to a certain depth, such that each of the clamping portions of each of the clamping elastic arms 221 together elastically clamp each of the notches 3221 of two sides of each of the positioning tracks 322 to form a positioning. Each of the guiding slopes 3223 is located on an end of the positioning track 322 corresponding to the fixing cover 22 and facing to the fixing cover 22, that is the guiding slope 3223 in each of the positioning tracks 322 is facing to the corresponding mounting wall 12. Therefore, the guiding slope 3223 may perform a guiding effect when each of the positioning tracks 322 is inserted into each of the plugging spaces 23, such that each of the positioning tracks 322 may be smoothly inserted into each of the plugging spaces 23 without directly impacting to the corresponding fixing cover 22 to cause lag or damage.

Please refer again to FIG. 1, FIG. 2, FIG. 3, FIG. 5, FIG. 7, FIG. 8, and FIG. 10. Each of the connecting assemblies 32 further includes a mounting side plate 323. In each of the connecting assemblies 32, the mounting side plate 32 is arranged on a side of the server body 31, the abutting plate 321 is arranged on the mounting side plate 323 along the longitudinal direction and substantially parallel to each of the carrying brackets 20, and the positioning track 322 is arranged on the mounting side plate 323 and substantially perpendicular to the abutting plate 321. In detail, each of the positioning tracks 322 in each of the connecting assemblies 32 is arranged on the mounting side plate 323 first, each of the positioning tracks 322 is substantially parallel to an up-down direction of the cabinet body 10, and then the abutting plate 321 is fixed on the positioning track 322 to be substantially perpendicular to each of the positioning tracks 322, as shown in FIG. 8 and FIG. 10. In addition, each of the connecting assemblies 32 further includes a fixing member 324. In each of the connecting assemblies 32, the fixing member 324 passes through the abutting plate 321 and is fixed to the corresponding frame body 21 to fix the abutting plate 321 on the corresponding frame body 21, so as to prevent the server module 30 from being bumped or vibrated where the bump and the vibration make each of the positioning tracks 322 to detach from the corresponding clamping elastic arms 221. In the embodiment, each of the connecting assemblies 32 includes a pair of fixing members 324 and each of the fixing members 324 is, for example, a bolt, and the frame body 21 defines a plurality of screw holes 212, but the present disclosure is not limited to this embodiment. Therefore, each of the fixing members 324 passes through the abutting plate 321 and screws in the corresponding screw holes 212 such that the abutting plate 321 may be stably fixed on the corresponding frame body 21 without rotating.

In the immersion server cabinet of the present disclosure, each of the fixing covers 22 and each of the grooves 211 of each of the frame bodies 21 together form the plugging space 23 such that each of the positioning tracks 322 of the server module 30 may be respectively inserted into each of the plugging spaces 23 and clamped and fixed by each of the clamping elastic arms 221 of the fixing cover 22. Each of the abutting plates 321 is placed on each of the frame bodies 21 to support such that the server module 30 may be mounted stably between the carrying brackets 20. The immersion server cabinet of the present disclosure may absorb vibration or shaking of the server module 30 through each of the clamping elastic arms 221 of the carrying brackets 20 during transportation.

What is claimed is:

1. An immersion server cabinet, comprising:
a cabinet body, comprising a chamber and a pair of mounting walls, each of the mounting walls respectively located on two opposite sides of the chamber;
a pair of carrying brackets, respectively arranged on each of the mounting walls, each of the carrying brackets comprising a frame body and a fixing cover, each of the frame bodies comprising a groove, each of the fixing covers comprising a pair of clamping elastic arms, the fixing cover of each of the carrying brackets mounted on the frame body and forming a plugging space with the groove; and
a server module, detachably connected to each of the carrying brackets and accommodated in the chamber, the server module comprising a server body and a pair of connecting assemblies, each of the connecting assemblies arranged on two opposite sides of the server body, each of the connecting assemblies comprising an abutting plate and a positioning track, each of the abutting plates respectively placed on each of the frame bodies, each of the positioning tracks respectively inserted into each of the plugging spaces and clamped and fixed by each of the clamping elastic arms.

2. The immersion server cabinet according to claim 1, wherein each of the fixing covers comprises a cover shell and a pair of mounting portions, in each of the fixing covers, each of the mounting portions is connected to two opposite sides of the cover shell, each of the mounting portions is arranged on the corresponding frame body and located two sides of the corresponding groove, the cover shell and the corresponding groove together form the plugging space, each of the clamping elastic arms is oppositely extended from the shell cover.

3. The immersion server cabinet according to claim 2, wherein each of the clamping elastic arms comprises a shrinking section and an expanding section, in each of the fixing cover, each of the shrinking sections is extended obliquely from the cover shell toward the other shrinking section, each of the expanding sections is extended from the corresponding shrinking section away from the other expanding section, a turning point between the shrinking section and the expanding section of each of the clamping elastic arms of each of the fixing covers is configured to be adjacent to a central area of each of the clamping elastic arms to form a clamping structure with the turning point inward and an opening outward.

4. The immersion server cabinet according to claim 1, wherein each of the positioning tracks comprises a pair of notches arranged opposite to each other, each of the clamping elastic arms elastically clamps each of the notches of two sides of each of the positioning tracks.

5. The immersion server cabinet according to claim 1, wherein each of the connecting assemblies comprises a pair of positioning tracks, in each of the connecting assemblies, each of the positioning tracks is configured to be perpendicular to the abutting plate.

6. The immersion server cabinet according to claim 1, wherein each of the positioning tracks comprises a guiding slope, each of the guiding slopes is located on an end of the positioning track corresponding to the fixing cover and facing to the fixing cover.

7. The immersion server cabinet according to claim 1, wherein each of the connecting assemblies further comprises a mounting side plate, in each of the connecting assemblies, the mounting side plate is arranged on a side of the server body, the abutting plate is arranged on the mounting side plate and parallel to each of the carrying brackets, the positioning track is arranged on the mounting side plate and perpendicular to the abutting plate.

8. The immersion server cabinet according to claim 1, wherein in each of the connecting assemblies, the abutting plate is fixed on the positioning track.

9. The immersion server cabinet according to claim 1, wherein the fixing cover of each of the carrying brackets is mounted on a side of the frame body away from the other carrying bracket.

10. The immersion server cabinet according to claim 1, wherein each of the connecting assemblies further comprises a fixing member, in each of the connecting assemblies, the fixing member passes through the abutting plate and is fixed to the corresponding frame body.
